(19) United States
(12) Patent Application Publication
(10) Pub. No.: US 2008/0124823 A1
(43) Pub. Date: May 29, 2008

(54) METHOD OF FABRICATING PATTERNED LAYER USING LIFT-OFF PROCESS

(75) Inventors: Pei-Wen Ko, Taipei City (TW); Da-Shuang Kuan, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: UNITED MICRODISPLAY OPTRONICS CORP., Hsin-Chu City (TW)

(21) Appl. No.: 11/563,037

(22) Filed: Nov. 24, 2006

(51) Int. Cl. H01L 21/00

(52) U.S. Cl. 438/29

(57) ABSTRACT

Method of fabricating patterned layers using lift-off processes is disclosed. A patterned stacked layer is formed on a substrate. The patterned stacked layer consists of a sacrificed layer and a photoresist layer, which covers and extends out of the sacrificed layer. Next, a film layer having a thickness smaller than that of the sacrificed layer is formed on the patterned stacked layer and gaps between the patterned stacked layer. Then, the photoresist layer and the film layer disposed on the photoresist layer are removed using a lift-off process; finally the sacrificed layer is removed.

### BACKGROUND OF THE INVENTION

1. Field of the Invention

The present invention relates to a method of fabricating patterned layers, and more particularly, to a method of fabricating patterned layers using lift-off processes.

2. Description of Related Art

In the integrated circuit manufacturing process, the method for forming the patterned layer is usually by depositing a film layer on a surface of the substrate and then the film layer is patterned by using a photolithographic process and an etching process. However, this method experienced some problems when dealing with thicker layers and thus studies on method of fabricating patterned layers using a lift-off process have been evaluated.

For example, a color filter is capable of filtering the lights emitted from a light source and has become indispensable element to many displaying devices. The color filter is usually formed by interlacing and stacking several film layers which have different refraction indices from each other so that the filter can filter off certain wavelength. In the process for forming the filter possessing composite layered structure, the film layers with different refraction indices are formed on the substrate sequentially and then the film layers are patterned by using sputtering etching process. However, the thickness of the common filter is larger than 8000 angstrom. When the conventional etching process is performed, the etching rate is so slow that the time for performing the etching process is too long and the etching rate is not even close to that is required for mass production. Hence, the conventional etching process cannot effectively mass produce color filters.

Another method for fabricating a color filter is by performing the lift-off process. First, forming an inverted trapezium photoresist layer on the substrate; next, the film layers with different refraction indices are formed on the substrate sequentially to cover the photoresist layer and the gaps in the photoresist layer. It is becoming more difficult for the sidewalls to be covered by the film layers when the angle of the inverted trapezoid getting larger; therefore, the photoresist layers and the film layers disposed above the photoresist layers can be removed by using a lift-off process and thus the film layers on the substrate remain exposed.

The material used for the photoresist layer is often the negative photoresist, wherein the angle of the inverted trapezoid will be affected by the thickness of the photoresist layer and the reaction of the photo-resistant agent. During the fabricating process, the angle of the inverted trapezoid is controlled by the exposure dose interacted with the baking temperature after exposure and thus making the angle of the inverted trapezoid confined, and the larger-angled inverted trapezoid becomes impossible. As shown in FIG. 1, during the process of forming a film layer 14, the film layer 14 can cover not only a substrate 10 but also the upper surface of an inverted trapezium photoresist layer 12; it can even cover up the sidewalls completely due to the angle of the inverted trapezoid of the photoresist layer 12 is not large enough. Furthermore, it is almost impossible to fabricate the patterned layer by using a lift-off process.

On the other hand, sometimes a T-shaped photoresist layer is used to fabricate patterned layers by using a lift-off process; even though it can satisfied the requirement of forming the patterned layer, it also increases difficulty for the photolithographic process.

### SUMMARY OF THE INVENTION

In view of the foregoing, this invention provides a method of fabricating patterned layers by using a lift-off process, which is easy, controllable and suitable for mass production.

This invention provides a method of fabricating patterned layers using lift-off process. First of all, a stacked patterned layer, which includes a sacrificed layer and a photoresist layer are formed on the substrate, wherein the photoresist layer covers and extends out of the sacrificed layer. Next, a film layer is formed on the stacked patterned layer and in gaps in the stacked patterned layer, and the thickness of the film layer is smaller than that of the sacrificed layer. Then, the film layer is removed together with the photoresist layer by using a lift-off process. Afterwards, the sacrificed layer is removed.

According to one embodiment of the present invention, the method for forming the stacked patterned layer is first to form a sacrificed material layer and a photoresist material layer subsequently on a substrate. Next, the photoresist material layer is patterned to form the aforementioned photoresist layer. Then, the patterns of the photoresist layer are transferred to the sacrificed material layer. Followed by removing a part of the sacrificed material layer disposed at the lower edge of the photoresist layer by using, for example, a wet etching process and the said sacrificed layer is formed, wherein the photoresist layer extends out of the sacrificed layer.

According to one embodiment of the present invention, the method for forming the stacked patterned layer is first to form a sacrificed material layer and a photoresist material layer subsequently on a substrate. Next, the photoresist material layer is patterned to form the aforementioned photoresist layer. Then, a wet etching process is performed to remove the exposed sacrificed material layer and a part of the sacrificed material layer disposed at the lower edge of the photoresist layer to form the aforementioned sacrificed layer and making the photoresist layer extend out of the sacrificed layer.

According to one embodiment of the present invention, the material of the sacrificed layer includes inorganic substances, such as silicon oxide, silicon nitride or silicon oxynitride.

According to one embodiment of the present invention, the aforementioned film layer includes a color filter film.

The present invention provides a method of fabricating patterned layers using lift-off process. The method is first to form a stacked patterned layer, which is formed by a sacrificed layer and a first photoresist layer on a substrate, wherein the first photoresist layer covers and extends out of the sacrificed layer. Next, a first film layer is formed on the stacked patterned layer and in gasps in the stacked patterned layer, and the thickness of the film layer is smaller than that of the said sacrificed layer. Then, the first photoresist layer and the first film layer disposed above the first photoresist layer are removed using a lift-off process. A second photoresist layer is formed on the first film layer. Then, the sacrificed layer is removed to expose the substrate. Afterwards, a second film layer is formed on the second photoresist layer and the exposed substrate. Then, the second photoresist layer and the second film layer disposed above the second photoresist layer are removed using a lift-off process.

According to one embodiment of the present invention, the method for forming the said stacked patterned layer is to form a sacrificed material layer and a first photoresist material layer subsequently on a substrate. Next, the first photoresist material layer is patterned to form the first photoresist layer. Then, the patterns of the first photoresist layer are transferred to the sacrificed material layer. Followed by removing part of the sacrificed material layer disposed on the lower edge of the first photoresist layer by using, for example, a wet etching process and the said sacrificed layer is formed, wherein the first photoresist layer extends out of the sacrificed layer.

According to one embodiment of the present invention, the method for forming the said stacked patterned layer is to form a sacrificed material layer and a first photoresist material layer subsequently on said substrate. Next, the first photoresist material layer is patterned to form the first photoresist layer. Then, a wet etching process is performed to remove a part of the aforementioned sacrificed material layer and thus a undercut gap between the remaining sacrificed layer and the first photoresist layer is formed.

According to one embodiment of the present invention, the above described steps of removing the said sacrificed layer include performing a dry etching process using the second photoresist layer as a mask.

According to one embodiment of the present invention, the dry etching process further comprises removing the said first film layer which is not covered by the second photoresist layer.

According to one embodiment of the present invention, the material of the said sacrificed layer includes inorganic substances, such as silicon oxide, silicon nitride and silicon oxynitride.

According to one embodiment of the present invention, the aforementioned first film layer and the second film layer are color filters of different colors.

The present invention provides a method of fabricating patterned layers by using lift-off process, which is easy, controllable and suitable for mass production.

In order to the make aforementioned and other objects, features and advantages of the present invention comprehensible, a preferred embodiment accompanied with figures are described in detail below.

### BRIEF DESCRIPTION OF THE DRAWINGS

FIG. 1 is schematic cross-sectional view showing a conventional method of fabricating a color filter using lift-off process.

FIGS. 2A through 2H are schematic cross-sectional views illustrating a process of fabricating patterned layers using lift-off process according to an embodiment of the present invention.

FIGS. 3A through 3G are schematic cross-sectional views illustrating a process of fabricating patterned layers using lift-off process according to another embodiment of the present invention.

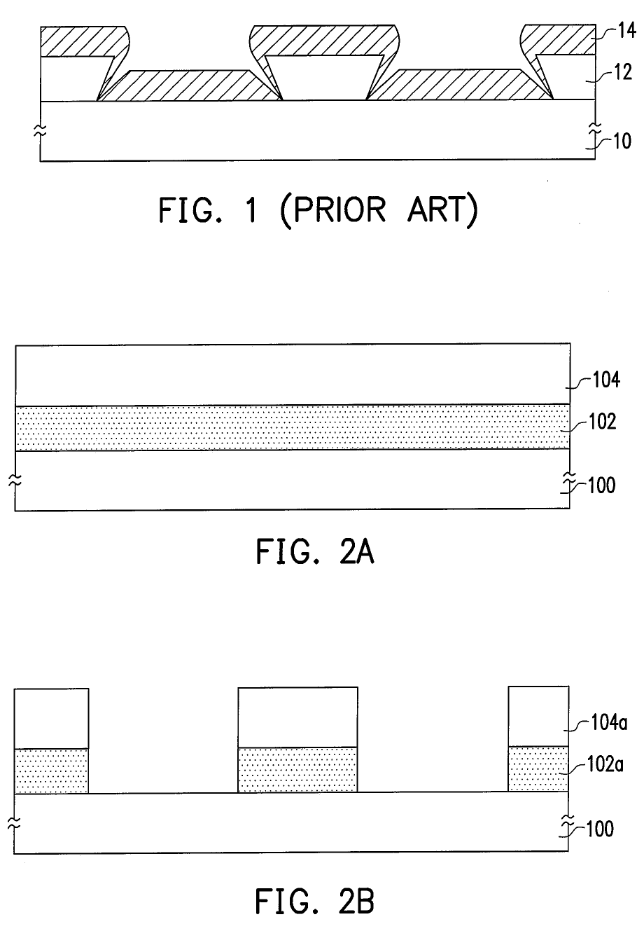

### DESCRIPTION OF EMBODIMENTS

The present invention provides a method of fabricating patterned layers using lift-off process, which is performed by using the patterned stacked layer consisted of the sacrificed layer and the photoresist layer. A required pattern, such as T sharp or T-like patterned stacked layers, is easily formed by way of controlling the conventional photolithography process and etching process. Therefore, after the film layer is deposited, it is easily to remove the photoresist layer and the film layer disposed on the photoresist layer. The sacrificed layer, which is removed by the follow-up etching process, will not remain. In an embodiment of the present invention, the remaining space after the sacrificed layer is removed, is used for forming another patterned layer.

### First Embodiment

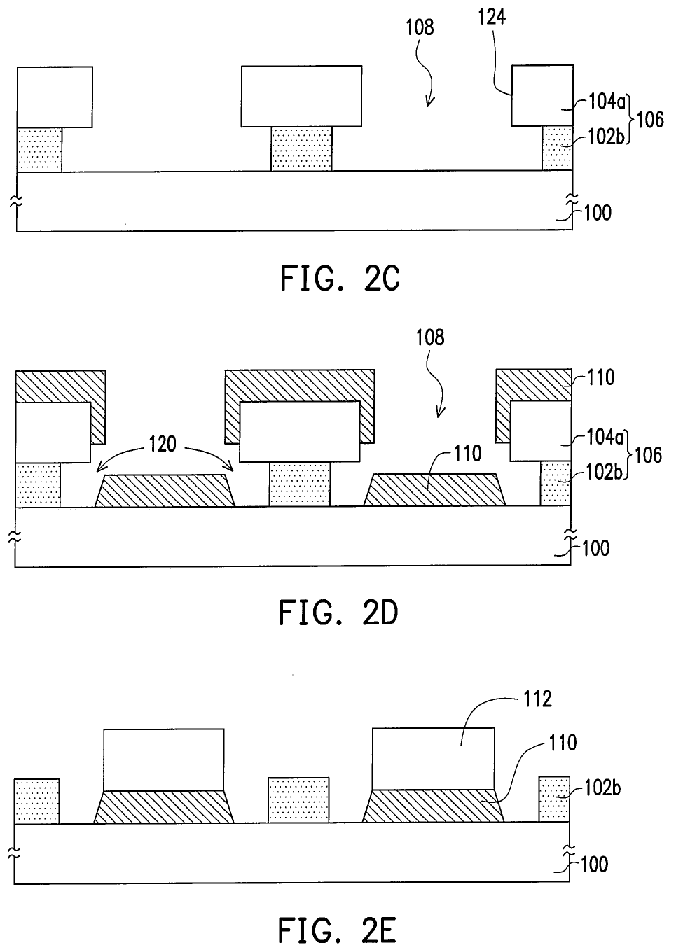

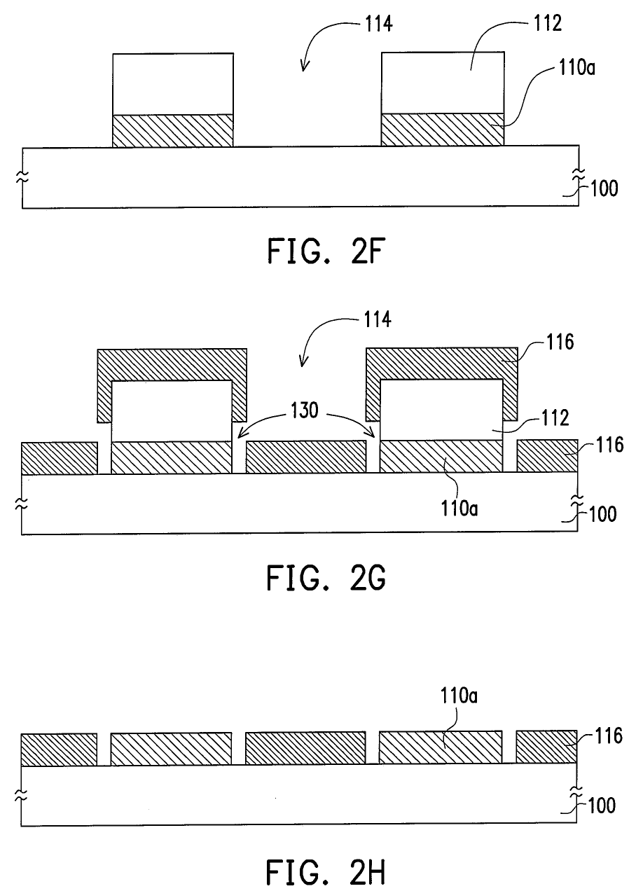

FIGS. 2A through 2H are schematic cross-sectional views illustrating a process of fabricating patterned layers using a lift-off process according to an embodiment of the present invention.

Referring to FIG. 2A, a sacrificed layer 102 and a photoresist layer 104 are subsequently formed on a substrate 100. The material of the sacrificed layer 102 includes, for example, inorganic materials, such as silicon oxide, silicon nitride or silicon oxynitride. The thickness of the sacrificed layer 102 is related to the predetermined patterned layer and the better thickness is larger than that of the predetermined patterned layer. In one embodiment, the thickness of the predetermined patterned layer is 1 μm and the thickness of the sacrificed layer 102 is, for example, 1.2 to 2.0 μm. The photoresist layer 104 is made of, for example, a positive photoresist or a negative photoresist, and the thickness is for example, 2.0 to 3.0 μm.

Next, referring to FIG. 2B, the photoresist layer 104 is patterned to form a patterned photoresist layer 104a. Then, using the patterned photoresist layer 104a as a mask, an anisotropic etching process is carried out on the sacrificed layer 102 to form a sacrificed layer 102a. The fabricating process of the photoresist layer 104a is really easy since it does not need to be patterned to form a shape of an inverted trapezoid or T type, nor does it need to be exposed in a special exposure dose or concern the baking temperature after exposure.

After that, please refer to FIG. 2C, a wet etching process is performed to remove a part of the sacrificed layer 102a located at the lower edge of sides 124 of the photoresist layer 104a to form a sacrificed layer 102b. A stacked patterned layer 106 with the cross-section shape of a T is formed by the sacrificed layer 102b and the photoresist layer 104a, which is extended out of the sacrificed layer 102b. In one embodiment, the material of the sacrificed layer 102 is silicon oxide, and the above mentioned wet etching process can use a hydrofluoric acid solution, for example, an Buffer Oxide Etcher (BOE) etching solution, wherein the 40% NH₄F; 49% HF in the ratio of 6:1 in volume. In one embodiment, the material of the sacrificed layer 102 is silicon nitride or silicon oxynitride and the above mentioned wet etching process can use, for example, a hot phosphoric acid as an etchant to perform.

Thereafter, as shown in FIG. 2D, a first film layer 110 is formed on the stacked patterned layer 106 and the substrate 100 of a gap 108 located in the stacked patterned layer 106. The thickness of the first film layer 110 is, for example, 0.8 to 1 μm, which is smaller than that of the sacrificed layer 102b. The first film layer 110 is a stacked color filter layer, which is formed by interlacing and stacking several film layers having different refraction indices. For example, the first film layer 110 can be formed by stacking the film layers on the substrate 100 in an order from the film layer with a relatively lower refraction index to the film layer with a relatively higher refraction index. Alternatively, in another embodiment, the first film layer 110 can be, for example, formed by stacking the film layers on the substrate 100 in an order from the film layer with a relatively higher refraction index to the film layer with a relatively lower refraction index. The first film layer 110 can be formed, for example, by stacking the film layers made of titanium dioxide and silicon dioxide or by the stacking film layers made of tantalum oxide (Ta₂O₅) and silicon dioxide. During the process of depositing the first film layer 110, since the photoresist layer has a thickness of 2 to 3 μm so as to provide the function as a collimator and thus the first film layer 110 is not easily deposited on the substrate 100 disposed under the photoresist layer 104a or on the sidewalls of the sacrificed layer 102b. Furthermore, since the thickness of the first film layer 110 is smaller than that of the sacrificed layer 102b, the first film layer 110 formed on the stacked patterned layer 106 and the first film layer 110 formed in the gap 108, which is located in the stacked patterned layer 106, will not connect to each other. That is, there is still a gap 120 existed between the photoresist layer 104a and the first film layer 110, which is formed in the gap 108 in the stacked patterned layer 106.

Next, referring to FIG. 2E, the first photoresist layer 104a and the first film layer 110 disposed above the first photoresist layer 104a are removed by using an etchant through the gap 120. Then, a photoresist layer 112 is formed on the first film layer 110. The photoresist layer 112 is made of, for example, a positive photoresist or a negative photoresist, and the thickness is for example, 2.0 to 3.0 μm.

After that, referring to FIG. 2F, a dry etching process is performed to remove the sacrificed layer 102b and expose the substrate 100. And, if the shape of the previously deposited first film layer 110 is roughly like a trapezoid, it can simultaneously remove the portion which is not covered by the photoresist layer 112 and correct the first film layer 110 to become the first film layer 110a during the process of dry etching. When the present invention applied to the color filters, cross-talk problem is avoided since the shape of the first film layer 110 has been corrected.

Next, as shown in FIG. 2G, a second film layer 116 is formed on the substrate 100 of a gap 114 in the photoresist layer 112 and the second photoresist layer 112. The second film layer 116 is a stacked color filter layer, which is formed by interlacing and stacking several film layers having different refraction indices. For example, the second film layer 116 can be formed by stacking the film layers on the substrate 100 in an order from the film layer with a relatively lower refraction index to the film layer with a relatively higher refraction index. Alternatively, in another embodiment, the second film layer 116 can be, for example, formed by stacking the film layers on the substrate 100 in an order from the film layer with a relatively higher refraction index to the film layer with a relatively lower refraction index. The second film layer 116 can be formed, for example, by stacking the film layers made of titanium dioxide and silicon dioxide or by the stacking film layers made of tantalum oxide (Ta₂O₅) and silicon dioxide. In an embodiment, the first film layer 110 is, for example, a blue light filter film layer; and the second film layer 116, for example, a green light filter film layer. In another embodiment, the first film layer 110 is, for example, a green light filter film layer; and the second film layer 116, for example, a blue light filter film layer. Since the thickness of the second film layer 116 is smaller than that of the photoresist layer 112, the second film layer 116 formed on the photoresist layer 112 and the second film layer 116 formed on the gap 114, will not connect to each other. In other words, there is still a gap 130 existed between the photoresist layer 112 and the second film layer 116, which is formed on the gap 114.

Thereafter, please refer to FIG. 2H, the second photoresist layer 112 and the second film layer 116 disposed above the second photoresist layer 112 are removed by using an etchant through the gap 130 and leaving the second film layer 116 located in the gap 114 of the first film layer 110a.

### Second Embodiment

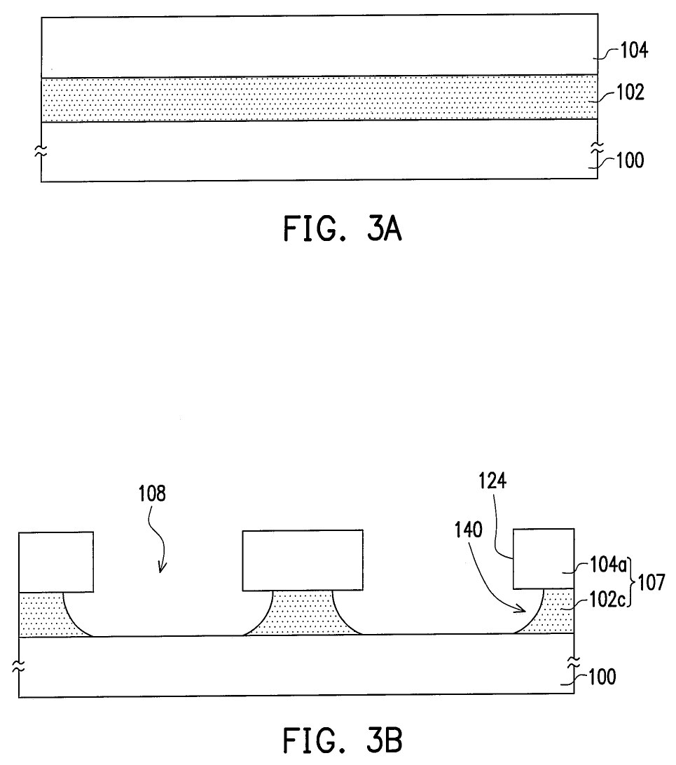

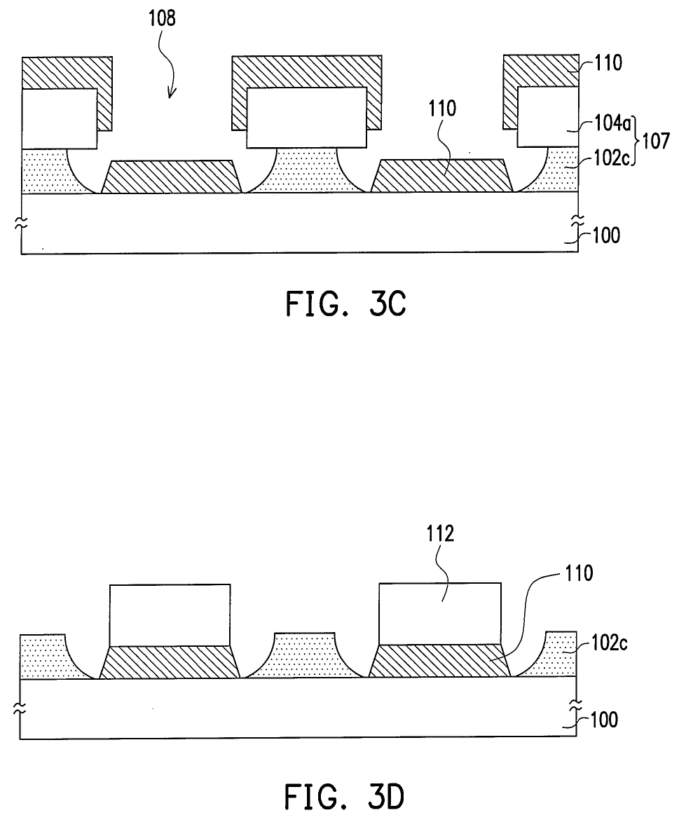

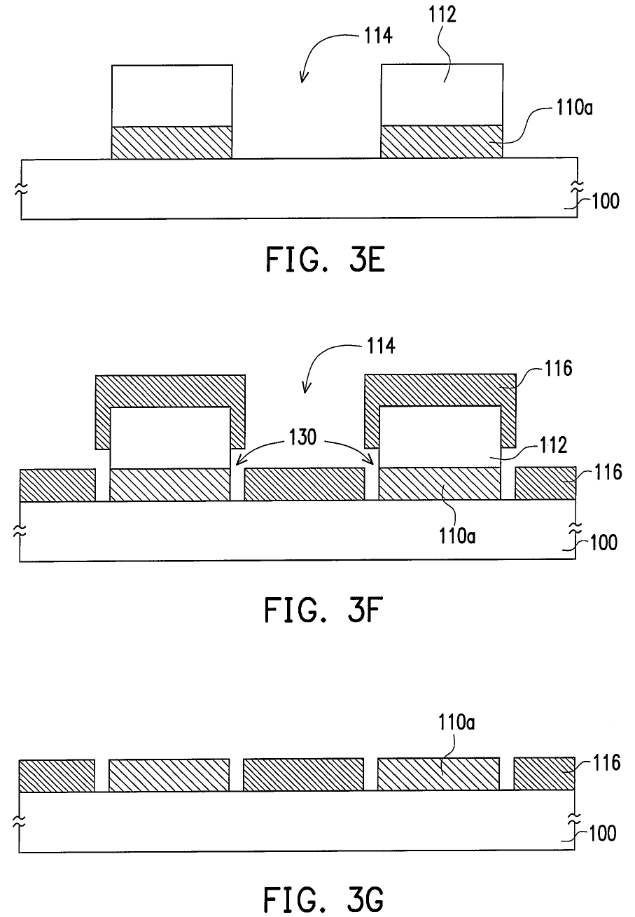

FIGS. 3A through 3G are schematic cross-sectional views illustrating a process of fabricating patterned layers using lift-off process according to another embodiment of the present invention.

Referring to FIG. 3A, the sacrificed layer 102 and the photoresist layer 104 are subsequently formed on the substrate 100. The materials and the steps of forming the sacrificed layer 102 and the photoresist layer 104 may refer to the first embodiment of the present invention.

Next, referring to FIG. 3B, the photoresist layer 104 is patterned to form a patterned photoresist layer 104a. Then, a wet etching process is performed to remove the sacrificed layer 102 and part of the sacrificed layer 102 located at the lower edge of the sidewalls and thus making a undercut gap 140 between the remaining sacrificed layer 102c and the photoresist layer 104a. A patterned stacked layer 107 with the cross-section of a T-like shape is formed by the sacrificed layer 102c and the photoresist layer 104a. In an embodiment, the material of the sacrificed layer 102 is silicon oxide, and the above mentioned wet etching process can use a hydrofluoric acid solution, for example, an etching solution Buffer Oxide Etcher (BOE), wherein the 40% NH₄F; 49% HF in the ratio of 6:1 in volume. In an embodiment, the material of the sacrificed layer 102 is silicon nitride or silicon oxynitride and the above mentioned wet etching process can use, for example, a hot phosphoric acid as an etchant to perform.

Then, as shown in FIGS. 3C to 3G, the first film layer 110a and the second film layer 116 are formed on the substrate 100 according to the steps illustrated in FIGS. 2D to 2H in the aforementioned embodiment.

The present invention provides a method of fabricating patterned layers by using lift-off process, which is easy, controllable and suitable for mass production.

What is claimed is:

1. A method of fabricating patterned layers using lift-off process, comprising: providing a substrate;
forming a stacked patterned layer on the substrate, wherein the stacked patterned layers is consist of a sacrificed layer and a first photoresist layer, and the photoresist layer covers and extends out of the sacrificed layer; forming a film layer on the stacked patterned layer and in gaps in the stacked patterned layer, and the thickness of the film layer is smaller than that of the sacrificed layer;
using the lift-off process to remove the photoresist layer and the film layer on the photoresist layer; and removing the sacrificed layer.

2. The method of fabricating patterned layers using lift-off process as claimed in claim 1, wherein the step of forming the stacked patterned layer comprises: forming a sacrificed material layer and a photoresist material layer on the substrate sequentially;
patterning the photoresist material layer to form the photoresist layer;
transferring patterns of the photoresist layer to the sacrificed material layer; and
forming the sacrificed layer by removing a part of the sacrificed material layer disposed at the lower edge of the photoresist layer, so that the photoresist layer is extended out of the sacrificed layer.

3. The method of fabricating patterned layers using lift-off process as claimed in claim 2, wherein the method of removing part of the sacrificed material layer disposed at the lower edge of the photoresist layer includes a wet etching process.

4. The method of fabricating patterned layers using lift-off process as claimed in claim 1, wherein the step of forming the stacked patterned layer comprises:
forming a sacrificed material layer and a photoresist material layer on the substrate sequentially;
patterning the photoresist material layer to form the photoresist layer; and
performing a wet etching process to remove a exposed part of the sacrificed material layer and a part of the sacrificed material layer disposed at the lower edge of the photoresist layer, and to form the sacrificed layer, wherein the photoresist layer extends out of the sacrificed layer.

5. The method of fabricating patterned layers using lift-off process as claimed in claim 1, wherein the material of the sacrificed layer includes inorganic substances.

6. The method of fabricating patterned layers using lift-off process as claimed in claim 5, wherein the inorganic substances include silicon oxide, silicon nitride or silicon oxynitride.

7. The method of fabricating patterned layers using lift-off process as claimed in claim 1, wherein the film layer includes a color filter film.

8. A method of fabricating patterned layers using lift-off process, comprising:
providing a substrate;
forming a stacked patterned layer on the substrate, wherein the stacked patterned layer is consist of a sacrificed layer and a first photoresist layer, and the first photoresist layer covers and extends out of the sacrificed layer;
forming a first film layer on the stacked patterned layer and in gasps in the stacked patterned layer, and the thickness of the first film layer is smaller than that of the sacrificed layer;
removing the first photoresist layer and the first film layer disposed above the first photoresist layer using a lift-off process;
forming a second photoresist layer on the first film layer;
removing the sacrificed layers to expose the substrate;
forming a second film layer on the second photoresist layer and a plurality of exposed parts of the substrate; and
removing the second photoresist layer and the second film layer disposed above the second photoresist layer using a lift-off process.

9. The method of fabricating patterned layers using lift-off process as claimed in claim 8, wherein the step of forming the stacked patterned layers comprises: forming a sacrificed material layer and a photoresist material layer on the substrate sequentially;
patterning the first photoresist material layer to form the first photoresist layer;
transferring patterns of the first photoresist layer to the sacrificed material layer; and
forming the sacrificed layer by removing part of the sacrificed material layer disposed at the lower edge of the first photoresist layer, so that the first photoresist layer is extended out of the sacrificed layer.

10. The method of fabricating patterned layers using lift-off process as claimed in claim 9, wherein the method of removing a part of the sacrificed material layer disposed at the lower edge of the first photoresist layer includes a wet etching process.

11. The method of fabricating patterned layers using lift-off process as claimed in claim 8, wherein the step of forming the stacked patterned layer comprises:
forming a sacrificed material layer and a first photoresist material layer on the substrate sequentially;
patterning the first photoresist material layer to form the first photoresist layer; and
performing a wet etching process to remove a part of the sacrificed material layer and leaving an undercut gap between the remaining sacrificed layer and the first photoresist layer.

12. The method of fabricating patterned layers using lift-off process as claimed in claim 8, wherein the method of removing the sacrificed layer includes performing a dry etching process using the second photoresist layer as a mask.

13. The method of fabricating patterned layers using lift-off process as claimed in claim 12, wherein the dry etching process further comprises removing the first film layer which is not covered by the second photoresist layer.

14. The method of fabricating patterned layers using lift-off process as claimed in claim 8, wherein the material of the sacrificed layer includes inorganic substances.

15. The method of fabricating patterned layers using lift-off process as claimed in claim 14, wherein the inorganic substances include silicon oxide, silicon nitride or silicon oxynitride.

16. The method of fabricating patterned layers using lift-off process as claimed in claim 8, wherein the first film layer and the second film layer are color filters of different colors.
